(19) United States
(12) Patent Application Publication
(10) Pub. No.: US 2025/0363282 A1
(43) Pub. Date: Nov. 27, 2025

(54) ALTERNATIVE MAINBAND MODE

(71) Applicant: QUALCOMM Incorporated, San Diego, CA (US)

(72) Inventors: Ravindranath DODDI, Hyderabad (IN); Umamaheshwaran V., Salem (IN); Sanchana Vasan S., Coimbatore (IN); Ramacharan SUNDARARAMAN, San Jose, CA (US)

(21) Appl. No.: 18/673,954

(22) Filed: May 24, 2024

(51) Int. Cl. G06F 30/392; H01L 25/065

(52) U.S. Cl. CPC G06F 30/392; H01L 25/0655

(57) ABSTRACT

Various aspects of the present disclosure generally relate to wireless communication. In some aspects, a first semiconductor device included in a semiconductor package may communicate, via a sideband between the first semiconductor device and a second semiconductor device included in the semiconductor package, an indication of support for an alternative mainband mode associated with data transfer between the first semiconductor device and the second semiconductor device via one or more alternative mainbands. The first semiconductor device may communicate, via the sideband, an indication to enter the alternative mainband mode. Numerous other aspects are described.

### FIELD OF THE DISCLOSURE

Aspects of the present disclosure generally relate to wired communication and specifically relate to techniques, apparatuses, and methods for an alternative mainband mode.

### BACKGROUND

A semiconductor package may contain one or more semiconductor dies and one or more leads for connection to a higher-level system. Semiconductor dies that are disposed on the same semiconductor package may be interconnected. For example, the semiconductor dies may communicate with each other using a standard, such as universal chiplet interconnect express (UCIe). UCIe is a multi-protocol, on-package interconnect standard for connecting multiple semiconductor dies on the same semiconductor package.

### SUMMARY

Some aspects described herein relate to an apparatus. The apparatus may include a first semiconductor device included in a semiconductor package. The first semiconductor device may be configured to communicate, via a sideband between the first semiconductor device and a second semiconductor device included in the semiconductor package, an indication of support for an alternative mainband mode associated with data transfer between the first semiconductor device and the second semiconductor device via one or more alternative mainbands. The first semiconductor device may be configured to communicate, via the sideband, an indication to enter the alternative mainband mode.

Some aspects described herein relate to a method performed by a first semiconductor device included in a semiconductor package. The method may include communicating, via a sideband between the first semiconductor device and a second semiconductor device included in the semiconductor package, an indication of support for an alternative mainband mode associated with data transfer between the first semiconductor device and the second semiconductor device via one or more alternative mainbands. The method may include communicating, via the sideband, an indication to enter the alternative mainband mode.

Some aspects described herein relate to an apparatus included in a semiconductor package. The apparatus may include means for communicating, via a sideband between the apparatus and another apparatus included in the semiconductor package, an indication of support for an alternative mainband mode associated with data transfer between the apparatus and the other apparatus via one or more alternative mainbands. The apparatus may include means for communicating, via the sideband, an indication to enter the alternative mainband mode.

Aspects of the present disclosure may generally be implemented by or as a method, apparatus, system, computer program product, non-transitory computer-readable medium, user equipment, base station, network node, network entity, wireless communication device, and/or processing system as substantially described with reference to, and as illustrated by, the specification and accompanying drawings.

The foregoing paragraphs of this section have broadly summarized some aspects of the present disclosure. These and additional aspects and associated advantages will be described hereinafter. The disclosed aspects may be used as a basis for modifying or designing other aspects for carrying out the same or similar purposes of the present disclosure. Such equivalent aspects do not depart from the scope of the appended claims. Characteristics of the aspects disclosed herein, both their organization and method of operation, together with associated advantages, will be better understood from the following description when considered in connection with the accompanying drawings.

### BRIEF DESCRIPTION OF THE DRAWINGS

The appended drawings illustrate some aspects of the present disclosure, but are not limiting of the scope of the present disclosure because the description may enable other aspects. Each of the drawings is provided for purposes of illustration and description, and not as a definition of the limits of the claims. The same or similar reference numbers in different drawings may identify the same or similar elements.

FIG. 1 is a diagram illustrating an example of a semiconductor device, in accordance with the present disclosure.

FIG. 2 is a diagram illustrating an example of a semiconductor package, in accordance with the present disclosure.

FIG. 3 is a diagram illustrating an example of a mainband failure, in accordance with the present disclosure.

FIG. 4 is a diagram illustrating an example of faulty lane identification during initialization, in accordance with the present disclosure.

FIG. 5 is a diagram illustrating an example associated with an alternative mainband mode, in accordance with the present disclosure.

FIG. 6 is a diagram illustrating an example associated with data transfer via one or more alternative mainbands, in accordance with the present disclosure.

FIG. 7 is a diagram illustrating an example associated with an alternative mainband mode for faulty lane identification during initialization, in accordance with the present disclosure.

FIG. 8 is a diagram illustrating an example associated with a mainband status register, in accordance with the present disclosure.

FIG. 9 is a diagram illustrating an example associated with signaling for an alternative mainband mode, in accordance with the present disclosure.

FIG. 10 is a diagram illustrating an example process performed, for example, at a first semiconductor device included in a semiconductor package or an apparatus of the first semiconductor device, in accordance with the present disclosure.

### DETAILED DESCRIPTION

Various aspects of the present disclosure are described hereinafter with reference to the accompanying drawings. However, aspects of the present disclosure may be embodied in many different forms and is not to be construed as limited to any specific aspect illustrated by or described with reference to an accompanying drawing or otherwise presented in this disclosure. Rather, these aspects are provided so that this disclosure will be thorough and complete, and will fully convey the scope of the disclosure to those skilled in the art. One skilled in the art may appreciate that the scope of the disclosure is intended to cover any aspect of the disclosure disclosed herein, whether implemented independently of or in combination with any other aspect of the disclosure. For example, an apparatus may be implemented or a method may be practiced using various combinations or quantities of the aspects set forth herein. In addition, the scope of the disclosure is intended to cover an apparatus having, or a method that is practiced using, other structures and/or functionalities in addition to or other than the structures and/or functionalities with which various aspects of the disclosure set forth herein may be practiced. Any aspect of the disclosure disclosed herein may be embodied by one or more elements of a claim.

Several aspects of telecommunication systems will now be presented with reference to various methods, operations, apparatuses, and techniques. These methods, operations, apparatuses, and techniques will be described in the following detailed description and illustrated in the accompanying drawings by various blocks, modules, components, circuits, steps, processes, or algorithms (collectively referred to as “elements”). These elements may be implemented using hardware, software, or a combination of hardware and software. Whether such elements are implemented as hardware or software depends upon the particular application and design constraints imposed on the overall system.

A chiplet may be an integrated circuit designed for one or more dedicated functions. Examples of chiplets may include central processing units (CPUs), accelerators, input/output (I/O) tiles, or the like. Multiple chiplets may be included in a single semiconductor package. In some examples, the chiplets may communicate with each other using links, such as universal chiplet interconnect express (UCIe) links. For example, two chiplets may communicate with each other over a mainband and a sideband. A sideband may serve as a main control path between the chiplets, and a mainband may serve as a main data path between the chiplets.

In some cases, the mainband may experience a temporary or permanent failure caused by a fabrication defect, high operating temperatures, or the like. While the mainband remains down, the chiplets may be unable to transfer data to each other. In automotive use cases, for example, reliability is crucial for passenger safety, and mainband failures can ultimately endanger passengers.

Various aspects relate generally relate to an alternative mainband mode. Some aspects more specifically relate to chiplets entering an alternative mainband mode in response to a failure of a shared mainband. In some aspects, the chiplets may communicate over a shared sideband, which may remain functional during the failure of the shared mainband, to enter the alternative mainband mode. During the alternative mainband mode, the chiplets may transfer data to each other via one or more alternative mainbands on the semiconductor package.

Particular aspects of the subject matter described in this disclosure can be implemented to realize one or more of the following potential advantages. In some examples, by chiplets entering the alternative mainband mode, the described techniques can be used to help to enable data transfer between chiplets having a faulty shared mainband. As a result, for example, each chiplet may access peripheral devices of the other chiplet. In automotive use cases, enabling data transfer via the alternative mainband(s) may reduce risk of endangerment for passengers.

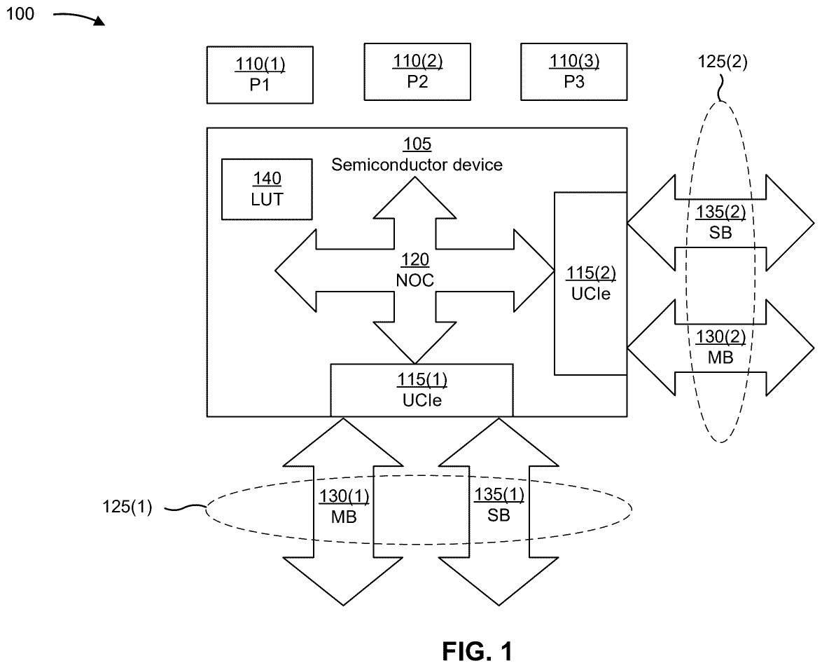

FIG. 1 is a diagram illustrating an example 100 of a semiconductor device 105, in accordance with the present disclosure.

In some examples, the semiconductor device 105 may comprise an integrated circuit, a semiconductor die, or the like. For example, the semiconductor device 105 may be a chiplet (e.g., an integrated circuit designed for one or more dedicated functions). As shown, the semiconductor device 105 may be associated with (e.g., may be connected to) peripheral devices 110(1)-110(3), which are shown as P1, P2, and P3, respectively. Whether a chiplet is associated with multiple peripheral devices may depend on system design.

The semiconductor device 105 may have one or more interfaces to UCIe ports 115(1) and 115(2). Additionally, or alternatively, semiconductor device 105 may have a network-on-chip (NOC) 120 that connects multiple components on the semiconductor device 105, peripheral devices 110(1)-110(3), the interfaces to the UCIe ports 115(1) and/or 115(2), or the like.

In some examples, the semiconductor device 105 may communicate with one or more other semiconductor devices (e.g., one or more other chiplets) that are in the same semiconductor package. The semiconductor devices may transmit messages over UCIe links 125(1) and/or 125(2) corresponding to the UCIe ports 115(1) and/or 115(2). For example, the semiconductor device 105 may be a target of a message, and/or the semiconductor device 105 may relay a message to another (remote) semiconductor device, via the UCIe links 125(1) and/or 125(2). The UCIe links 125(1) and 125(2) may be physical links configured for UCIe.

A UCIe link may comprise two connection bands: a sideband and a mainband. For example, as shown, the UCIe link 125(1) may include a mainband (“MB”) 130(1) and a sideband (“SB”) 135(1), and the UCIe link 125(2) may include a mainband 130(2) and a sideband 135(2). Generally, a sideband may be a main control path for UCIe, and a mainband may serve as a main data path for UCIe. For example, a sideband may be used for parameter exchanges, register accesses for debugging or compliance, and coordination with remote partners (e.g., semiconductor devices) for link training and management, or the like. A mainband may comprise a forwarded clock, a data valid pin, a track pin, and N lanes of data per module (e.g., per semiconductor device). The protocol for communication over a mainband between semiconductor devices may be common or interoperable. For example, the semiconductor device 105 may stream data and/or convert data to a peripheral component interconnect express (PCIe) format, a compute express link (CXL) format, or the like.

UCIe may support at least two packaging options: standard (e.g., two-dimensional) packaging and advanced (e.g., 2.5-dimensional) packaging. Standard packaging may be used for low-cost applications with long channel lengths (e.g., 10-25 mm). Advanced packaging may be used for performance-optimized applications with short channel lengths (e.g., less than 2 mm). In cases where UCIe is used as a device-to-device (D2D) interface, the semiconductor device 105 may use 16, 32, or 64 mainband lanes to transfer data to or from another semiconductor device. For example, in standard packaging, the mainband may have 16 data lanes; in advanced packaging, the mainband may have 64 data lanes.

The semiconductor device 105 may also include a lookup table (LUT) 140. The LUT 140 may contain routing information that is used for routing decisions in the NOC 120. For example, the LUT 140 may contain source information and destination information for messages. For example, the source information may identify a message source, such as sources within (e.g., local components of) the semiconductor device 105, peripheral devices 110(1)-110(3), UCIe links 125(1) and/or 125(2), or the like. The destination information may identify message destinations, such as destinations within (e.g., local components of) the semiconductor device 105, peripheral devices 110(1)-110(3), UCIe links 125(1) and/or 125(2), or the like. In some examples, the routing information may be based at least in part on identifiers (e.g., source identifiers or destination identifiers), physical address bits, or the like.

The LUT 140 may be stored on one or more components of the semiconductor device 105. For example, the LUT 140 may be physically distributed in the NOC 120, which may have any suitable topology (e.g., ad-hoc, two-dimensional mesh, ring, torus, or the like). In some examples, the LUT 140 may be programmed at design time (e.g., by system firmware with specific security privileges). In some examples, the LUT 140 may be accessible over sideband 135(1) and/or 135(2) and may be programmed or reprogrammed (e.g., after design time, such as during run time) to configure and/or update pairs of sources and destinations.

Implementations provided herein may enable the semiconductor device 105 to enter an alternative mainband mode in which the semiconductor device 105 can transfer data to, and/or receive data from, another semiconductor device. For example, in cases where the semiconductor device 105 is connected to the other semiconductor device via the mainband 130(1), the semiconductor device 105 may transfer or receive the data via at least the mainband 130(2). In some examples, the semiconductor device 105 may transfer or receive the data using the LUT 140.

As indicated above, FIG. 1 is provided as an example. Other examples may differ from what is described with respect to FIG. 1.

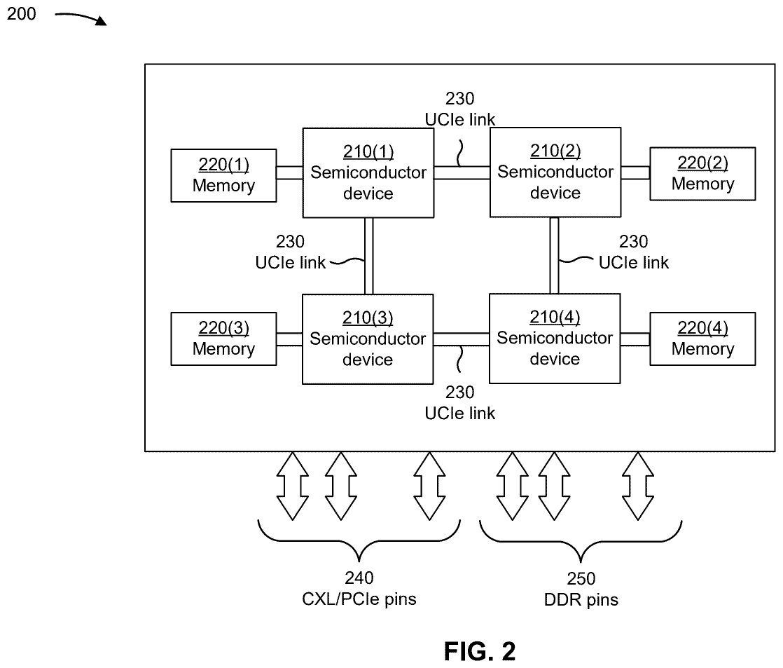

FIG. 2 is a diagram illustrating an example 200 of a semiconductor package, in accordance with the present disclosure.

The semiconductor package may include semiconductor devices 210(1)-210(4) (e.g., chiplets). For example, semiconductor devices 210(1) and 210(2) may be CPU dies, semiconductor device 210(3) may be an accelerator die, and semiconductor device 210(4) may be an input/output (I/O) tile (e.g., an I/O die). As shown, the semiconductor devices 210(1)-210(4) may be associated with (e.g., connected to) respective memory devices 220(1)-220(4).

The semiconductor devices 210(1)-210(4) may be interconnected within the semiconductor package via UCIe links 230. For example, the UCIe links 230 may include one or more mainbands and/or sidebands. The UCIe links 230 may enable the semiconductor devices 210(1)-210(4) to communicate with each other and thereby realize a target functionality of the semiconductor package. Implementations provided herein may enable a semiconductor device 210 to enter an alternative mainband mode in which the semiconductor device 210 can transfer data to, and/or receive data from, another semiconductor device 210 via one or more mainbands of one or more UCIe links 230.

In some examples, the semiconductor package may communicate with other semiconductor packages and/or other devices. For example, the semiconductor package may belong to a system that is based at least in part on chiplet architecture, such as a graphics processing unit (GPU), a server, a mobile or automotive system-on-chip (SOC), or the like. As shown, the semiconductor package may include one or more external CXL or PCIe pins 240, one or more external double data rate (DDR) pins 250, or the like.

As indicated above, FIG. 2 is provided as an example. Other examples may differ from what is described with respect to FIG. 2.

In some aspects, as described in more detail elsewhere herein, a first semiconductor device included in a semiconductor package may include means for communicating, via a sideband between the first semiconductor device and a second semiconductor device included in the semiconductor package, an indication of support for an alternative mainband mode associated with data transfer between the first semiconductor device and the second semiconductor device via one or more alternative mainbands; and means for communicating, via the sideband, an indication to enter the alternative mainband mode. The means for the first semiconductor device to perform processes and/or operations described herein may include one or more systems, devices, apparatuses and/or components of FIGS. 1-2, such as the semiconductor device 105, UCIe ports 115, UCIe links 125(1), mainbands 130, sidebands 135, semiconductor devices 210, UCIe links 230, and/or the like. Additionally, or alternatively, one or more systems, devices, apparatuses, and/or components of the FIGS. 1-2 may be configured to perform one or more other operations described herein.

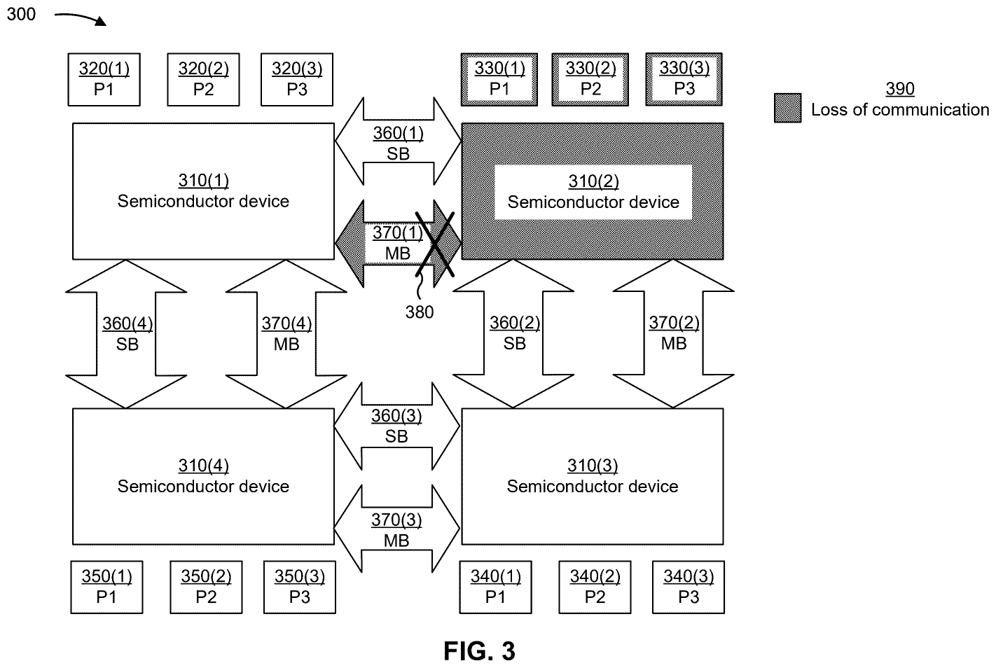

FIG. 3 is a diagram illustrating an example 300 of a mainband failure, in accordance with the present disclosure.

In some examples, a semiconductor package may include semiconductor devices 310(1)-310(4) (e.g., chiplets). The semiconductor package may also include peripheral devices 320(1), 330(1), 340(1), and 350(1) (shown as P1), peripheral devices 320(2), 330(2), 340(2), and 350(2) (shown as P2), and peripheral devices 320(3), 330(3), 340(3), and 350(3) (shown as P3). The semiconductor devices 310(1)-310(4) may be associated with (e.g., may be connected to) peripheral devices 320(1)-320(3), 330(1)-330(3), 340(1)-340(3), and 350(1)-350(3), respectively.

In some examples, the semiconductor devices 310(1)-310(4) may communicate with each other over sidebands 360 and mainbands 370. For example, the semiconductor devices 310(1) and 310(2) may communicate with each other over sideband 360(1) and mainband 370(1). The semiconductor devices 310(2) and 310(3) may communicate with each other over sideband 360(2) and mainband 370(2). The semiconductor devices 310(3) and 310(4) may communicate with each other over sideband 360(3) and mainband 370(3). The semiconductor devices 310(4) and 310(1) may communicate with each other over sideband 360(4) and mainband 370(4).

As shown by reference number 380, the mainband 370(1) (e.g., one or more data lanes of the mainband 370(1)) may experience a failure. For example, the failure may be caused by a fabrication defect, high temperatures, aging of one or more semiconductor dies, or the like. The failure may be temporary or permanent. Thus, the semiconductor package may enter a faulty mainband scenario during which the semiconductor devices 310(1) and 310(2) can no longer form a link over the mainband 370(1).

The semiconductor devices 310(1) and/or 310(2) may continually try to re-establish the link. While the link remains down, the semiconductor devices 310(1) and/or 310(2) may be unable to perform data transfer over the mainband 370(1) (e.g., one or more data lanes of the mainband 370(1)). As a result, during the failure, communication may be lost between the semiconductor devices 310(1) and 310(2). For example, as shown by reference number 390, the semiconductor device 310(1) may lose communication with semiconductor device 310(2) and/or peripherals 330(1)-330(3). In automotive use cases, for example, reliability is crucial for passenger safety, and mainband failures can ultimately endanger passengers.

Implementations provided herein may enable the semiconductor devices 310(1) and 310(2) to enter an alternative mainband mode in the event of the failure of the mainband 370(1). In the alternative mainband mode, the semiconductor devices 310(1) and 310(2) may communicate with each other via mainbands 370(2)-370(4).

As indicated above, FIG. 3 is provided as an example. Other examples may differ from what is described with respect to FIG. 3.

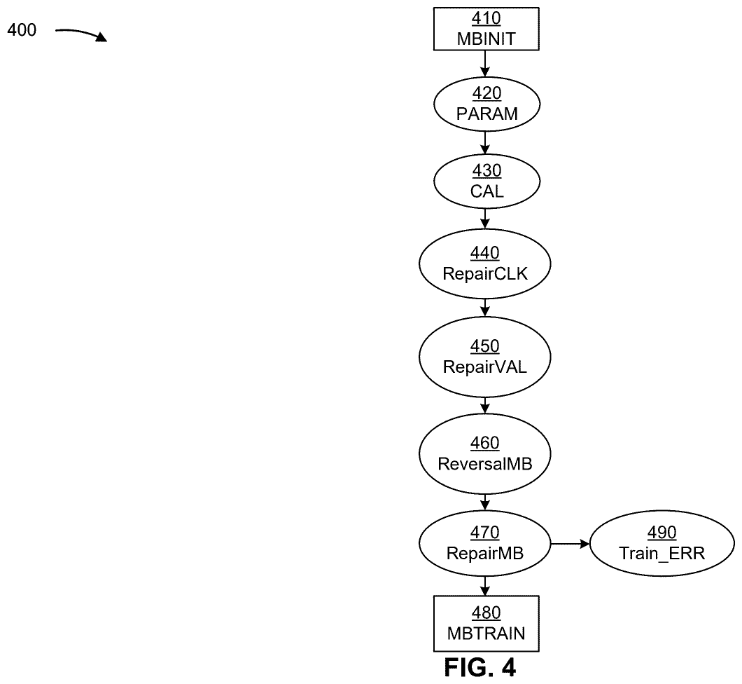

FIG. 4 is a diagram illustrating an example 400 of faulty lane identification during initialization, in accordance with the present disclosure.

In some examples, two semiconductor devices (e.g., two module partners, such as two chiplets) may establish a connection using a UCIe link training state machine. For example, a link (e.g., a UCIe link) between the two semiconductor devices may proceed through various states in a UCIe link training state machine. For example, the link may transition from a reset (RESET) state to a sideband initialization (SBINIT) state, from the SBINIT state to a mainband initialization (MBINIT) state, from the MBINIT state to a mainband training (MBTRAIN) state, from the MBTRAIN state to a link initialization (LINKINIT) state, and from the LINKINIT state to an active (ACTIVE) state. The RESET state may be an initial state for the link. The SBINIT state may establish a sideband of the link. The MBINIT state may establish a mainband of the link. The LINKINIT state may establish the link, and the ACTIVE state may activate the link.

Example 400 shows a plurality of substates of an MBINIT state 410. In a parameter exchange (PARAM) substate 420, the semiconductor devices may exchange one or more parameters in preparation for establishing the link. In a calibration (CAL) substate 430, the semiconductor devices may perform a voltage and/or clock calibration. In a clock repair (RepairCLK) substate 440, the semiconductor devices may determine whether a clock line is functional. In a valid lane repair (RepairVAL) substate 450, the semiconductor devices may exchange data framing information. In a mainband reversal (ReversalMB) substate 460, the semiconductor devices may format the link. In a mainband repair (RepairMB) substate 470, the semiconductor devices may repair a mainband. For example, for standard packages, the semiconductor devices may reduce a clock speed or link width; for advanced packages, the semiconductor devices may leverage redundant links. A substate may be referred to using the format “state.substate.” For example, the PARAM substate 420 may be referred to as an MBINIT.PARAM substate, the CAL substate 430 may be referred to as an MBINIT.CAL substate, and so forth.

In some examples (e.g., in cases where the link is functioning properly), the link may transition from the MBINIT.RepairMB substate 470 to the MBTRAIN state 480. In some examples (e.g., in cases where the link is not functioning properly, such as due to a mainband failure), the link may transition from the MBINIT.RepairMB substate 470 to a training error (Train_ERR) state 490. Generally, the link may transition to the Train_ERR state 490 in case of a link error in any other state. The link may transition from the Train_ERR state 490 to the RESET state, where the semiconductor devices may continually try to re-establish the link. While the link remains in the RESET state, the semiconductor devices may be unable to perform data transfer over the link (e.g., over a mainband of the link).

Implementations provided herein may enable the semiconductor devices, instead of transitioning the link to the Train_ERR state 490, to pause the UCIe link training state machine in the MBINIT.RepairMB substate 470 (e.g., by disabling a state residency timeout (e.g., of 8 ms) until the next auxiliary power domain reset). While the link is in the MBINIT. RepairMB substate 470, the semiconductor devices may enter an alternative mainband mode in which the semiconductor devices may communicate with each other via alternative mainbands.

As indicated above, FIG. 4 is provided as an example. Other examples may differ from what is described with respect to FIG. 4.

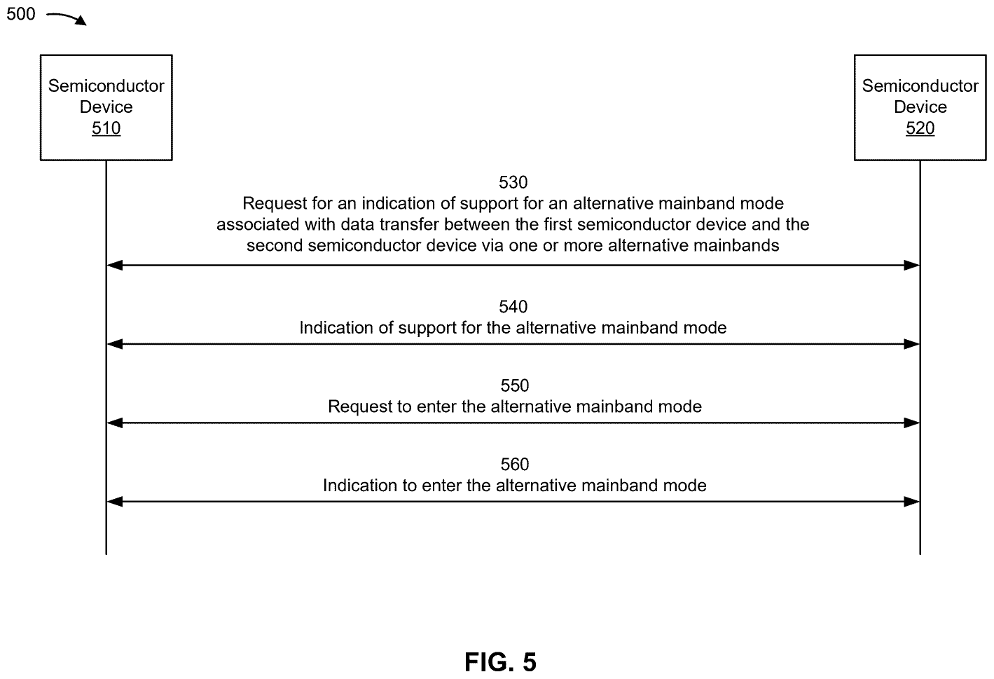

FIG. 5 is a diagram illustrating an example 500 associated with an alternative mainband mode, in accordance with the present disclosure. As shown in FIG. 5, a semiconductor device 510 and a semiconductor device 520 may communicate with one another. In some aspects, a semiconductor package may include the semiconductor device 510 and the semiconductor device 520. In some examples, the semiconductor device 510 and the semiconductor device 520 may be UCIe dies.

As shown by reference number 530, the semiconductor device 510 and the semiconductor device 520 may communicate a request for an indication of support for an alternative mainband mode. In some examples, the semiconductor device 510 may transmit, and the semiconductor device 520 may receive, the request for the indication of support for the alternative mainband mode. In some examples, the semiconductor device 520 may transmit, and the semiconductor device 520 may receive, the request for the indication of support for the alternative mainband mode. The semiconductor device 510 and the semiconductor device 520 may communicate the request for the indication of support for the alternative mainband mode via a sideband between the semiconductor device 510 and the semiconductor device 520.

The alternative mainband mode may be associated with data transfer between the semiconductor device 510 and the semiconductor device 520 via one or more alternative mainbands. The alternative mainband mode may be associated with data transfer between the semiconductor device 510 and the semiconductor device 520 via one or more alternative mainbands in that the semiconductor device 510 and the semiconductor device 520 may, while in the alternative mainband mode, transfer data (e.g., route responses) via the one or more alternative mainbands. For example, the semiconductor device 510 may transmit, and the semiconductor device 520 may receive, data via the one or more alternative mainbands. Additionally, or alternatively, the semiconductor device 520 may transmit, and the semiconductor device 510 may receive, data via the one or more alternative mainbands. In some examples, the one or more alternative mainbands may be mainbands in the semiconductor package. For example, the one or more alternative mainbands may be connected to one or more other semiconductor devices in the semiconductor package. For example, the one or more alternative mainbands and/or the one or more other semiconductor devices may connect the semiconductor device 510 and the semiconductor device 520.

As shown by reference number 540, the semiconductor device 510 and the semiconductor device 520 may communicate, via the sideband between the first semiconductor device and the second semiconductor device, an indication of support for the alternative mainband mode. In some examples (e.g., where the semiconductor device 520 transmits, and the semiconductor device 520 receives, the request for the indication of support for the alternative mainband mode), the semiconductor device 510 may transmit, and the semiconductor device 520 may receive, the indication of support for the alternative mainband mode. In some examples (e.g., where the semiconductor device 510 transmits, and the semiconductor device 520 receives, the request for the indication of support for the alternative mainband mode), the semiconductor device 520 may transmit, and the semiconductor device 510 may receive, the indication of support for the alternative mainband mode.

In some aspects, the semiconductor device 510 and the semiconductor device 520 may communicate the indication of support for the alternative mainband mode in a parameter exchange substate of a mainband initialization state. For example, the semiconductor device 510 and the semiconductor device 520 may communicate the indication of support for the alternative mainband mode in an MBINIT.param substate. For example, the semiconductor device 510 and the semiconductor device 520 may exchange the indication of support for the alternative mainband mode during mainband initialization (e.g., in an MBINIT state). Additionally, or alternatively, the semiconductor device 510 and the semiconductor device 520 may communicate the request for the indication of support for the alternative mainband mode in the MBINIT.param substate.

As shown by reference number 550, the semiconductor device 510 and the semiconductor device 520 may communicate a request to enter the alternative mainband mode. In some examples, the semiconductor device 510 may transmit, and the semiconductor device 520 may receive, the request to enter the alternative mainband mode. In some examples, the semiconductor device 520 may transmit, and the semiconductor device 520 may receive, the request to enter the alternative mainband mode. The semiconductor device 510 and the semiconductor device 520 may communicate the request to enter the alternative mainband mode via the sideband between the semiconductor device 510 and the semiconductor device 520.

As shown by reference number 560, the semiconductor device 510 and the semiconductor device 520 may communicate, via the sideband between the first semiconductor device and the second semiconductor device, an indication to enter the alternative mainband mode. In some examples (e.g., where the semiconductor device 520 transmits, and the semiconductor device 520 receives, the request to enter the alternative mainband mode), the semiconductor device 510 may transmit, and the semiconductor device 520 may receive, the indication to enter the alternative mainband mode. In some examples (e.g., where the semiconductor device 510 transmits, and the semiconductor device 520 receives, the request to enter the alternative mainband mode), the semiconductor device 520 may transmit, and the semiconductor device 510 may receive, the indication to enter the alternative mainband mode.

In some aspects, the semiconductor device 510 and the semiconductor device 520 may communicate the indication to enter the alternative mainband mode responsive to a failure of a mainband between the semiconductor device 510 and the semiconductor device 520. For example, the semiconductor device 510 and/or the semiconductor device 520 may detect the failure of the mainband between the semiconductor device 510 and the semiconductor device 520 and, in response to detecting the failure, communicate the request to enter the alternative mainband mode and/or communicate the indication to enter the alternative mainband mode. In some examples, the sideband between the semiconductor device 510 and the semiconductor device 520 may remain functional during the failure of the mainband between the semiconductor device 510 and the semiconductor device 520. Thus, for example, the semiconductor device 510 and the semiconductor device 520 may keep the sideband between the semiconductor device 510 and the semiconductor device 520 alive, and the sideband may carry the indication to enter the alternative mainband mode.

In some aspects, the semiconductor device 510 and the semiconductor device 520 may communicate the indication to enter the alternative mainband mode in a mainband repair substate of a mainband initialization state. For example, the semiconductor device 510 and the semiconductor device 520 may communicate the indication to enter the alternative mainband mode in an MBINIT.repair substate. For example, the semiconductor device 510 and the semiconductor device 520 may exchange the indication to enter the alternative mainband mode during mainband initialization (e.g., in an MBINIT state). Additionally, or alternatively, the semiconductor device 510 and the semiconductor device 520 may communicate the request to enter the alternative mainband mode in the MBINIT.repair substate.

For example, in the event of a failure of the mainband between the semiconductor device 510 and the semiconductor device 520 during link initialization, a link training state machine (e.g., a UCIe link training state machine) may transition to the MBINIT.repair substate. While the link between the semiconductor device 510 and the semiconductor device 520 is in the MBINIT.repair substate, the semiconductor device 510 and/or the semiconductor device 520 may attempt to repair the mainband. In some examples, if the mainband repair attempt is unsuccessful, and if the request to enter the alternative mainband mode is acknowledged (e.g., using the indication to enter the alternative mainband mode), then the semiconductor device 510 and/or the semiconductor device 520 may pause the link training state machine in the MBINIT.repair substate and disable a state residency timeout (e.g., 8 ms), and the link may transition to the alternative mainband mode until the next auxiliary power domain reset.

In some aspects, the semiconductor device 510 and/or the semiconductor device 520 may communicate, via the sideband between the semiconductor device 510 and the semiconductor device 520, in the alternative mainband mode, a reconfiguration of routing information associated with the one or more alternative mainbands. The routing information may be associated with the one or more alternative mainbands in that the routing information may indicate that the semiconductor device 510 and/or the semiconductor device 520 are to transfer data via the one or more alternative mainbands (e.g., instead of via a faulty mainband between the semiconductor device 510 and the semiconductor device 520). For example, in the alternative mainband mode, the semiconductor device 510 and/or the semiconductor device 520 may use the sideband lanes between the semiconductor device 510 and the semiconductor device 520 to communicate control information that reconfigures the routing information for transferring the data via the one or more alternative mainbands.

In some aspects, the semiconductor device 510 and/or the semiconductor device 520 may perform the data transfer via the one or more alternative mainbands. For example, the semiconductor device 510 and/or the semiconductor device 520 may transfer the data via the one or more alternative mainbands. At least one of the one or more alternative mainbands may be connected to the semiconductor device 510, and at least one of the one or more alternative mainbands may be connected to the semiconductor device 520. The one or more alternative mainbands may be interconnected and collectively form a path between the semiconductor device 510 and the semiconductor device 520. Thus, the data may be transferred between the semiconductor device 510 and the semiconductor device 520 via one or more data lanes of the one or more alternative mainbands.

In some examples, queue sizes (e.g., protocol layer buffers) may be adjusted on the semiconductor device 510 and the semiconductor device 520, which may enable the data transfer to meet an underlying round trip latency of the data transfer between the semiconductor device 510 and the semiconductor device 520 via the one or more alternative mainbands. In some examples, a system designer may define timeout values that avoid unnecessary timeouts based at least in part on an application of the semiconductor package. For example, the timeout values may be increased, which may account for the increased time involved in transferring the data between the semiconductor device 510 and the semiconductor device 520 via the one or more alternative mainbands, as compared to transferring the data between the semiconductor device 510 and the semiconductor device 520 via the mainband between the semiconductor device 510 and the semiconductor device 520. Thus, defining the timeout values that avoid unnecessary timeouts may help to improve the robustness of UCIe links.

As indicated above, FIG. 5 is provided as an example. Other examples may differ from what is described with respect to FIG. 5.

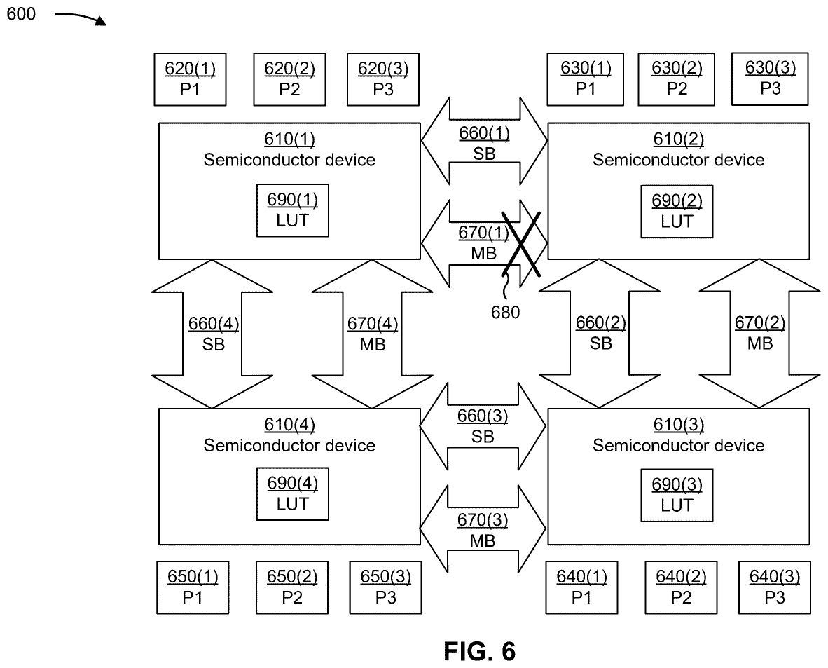

FIG. 6 is a diagram illustrating an example 600 associated with data transfer via one or more alternative mainbands, in accordance with the present disclosure.

In some examples, a semiconductor package may include semiconductor devices 610(1)-610(4) (e.g., chiplets) connected via UCIe. The semiconductor package may also include peripheral devices 620(1), 630(1), 640(1), and 650(1) (shown as P1), peripheral devices 620(2), 630(2), 640(2), and 650(2) (shown as P2), and peripheral devices 620(3), 630(3), 640(3), and 650(3) (shown as P3). The semiconductor devices 610(1)-610(4) may be associated with (e.g., may be connected to) peripheral devices 620(1)-620(3), 630(1)-630(3), 640(1)-640(3), and 650(1)-650(3), respectively.

In some examples, the semiconductor devices 610(1)-610(4) may communicate with each other over sidebands 660 and mainbands 670. For example, the semiconductor devices 610(1) and 610(2) may communicate with each other over sideband 660(1) and mainband 670(1). The semiconductor devices 610(2) and 610(3) may communicate with each other over sideband 660(2) and mainband 670(2). The semiconductor devices 610(3) and 610(4) may communicate with each other over sideband 660(3) and mainband 670(3). The semiconductor devices 610(4) and 610(1) may communicate with each other over sideband 660(4) and mainband 670(4).

As shown by reference number 680, the mainband 670(1) (e.g., one or more data lanes of the mainband 670(1)) may experience a failure. For example, the failure may be caused by a fabrication defect, high temperatures, or the like. The failure may be temporary or permanent. Thus, the semiconductor package may enter a faulty mainband scenario during which the semiconductor devices 610(1) and 610(2) can no longer form a link over the mainband 670(1).

In some examples, the semiconductor devices 610(1) and 610(2) may enter an alternative mainband mode. The alternative mainband mode may be associated with data transfer between the semiconductor devices 610(1) and 610(2) via one or more alternative mainbands. For example, the one or more alternative mainbands may comprise mainbands 670(2)-670(4). For example, the semiconductor devices 610(1) and 610(2) may perform the data transfer via the mainbands 670(2)-670(4).

As discussed in greater detail elsewhere herein, semiconductor devices (e.g., the semiconductor devices 610(1) and 610(2)) may communicate, via a sideband (e.g., the sideband 660(1)), in the alternative mainband mode, a reconfiguration of routing information associated with the one or more alternative mainbands. In some aspects, the routing information may be stored in LUTs 690(1)-690(4). For example, semiconductor devices 610(1)-610(4) may store LUTs 690(1)-690(4), respectively. For example, each semiconductor device 610 may store routing information to route messages (e.g., data) from one semiconductor device 610 to another semiconductor device 610 via one or more UCIe ports.

In some examples, in the event of the failure of the mainband 670(1), the semiconductor devices 610(1) and/or 610(2) may use the sideband 660(1) (which may remain functional) to update the routing information in the LUTs 690(1) and/or 690(2). Additionally, or alternatively, the semiconductor devices 610(1) and/or 610(2) may communicate (e.g., transmit), via the sidebands 660(2)-660(4), a reconfiguration of routing information in the LUTs 690(3) and/or 690(4).

The semiconductor devices 610(1) and 610(2) may perform the data transfer via the mainbands 670(2)-670(4). In some examples, the semiconductor device 610(1) may transfer the data to the semiconductor device 610(2). For example, the semiconductor device 610(1) may transmit, using the routing information in the LUT 690(1), the data to semiconductor device 610(4) via mainband 670(4); the semiconductor device 610(4) may transmit, using the routing information in the LUT 690(4), the data to semiconductor device 610(3) via mainband 670(3); and the semiconductor device 610(3) may transmit, using the routing information in the LUT 690(3), the data to semiconductor device 610(2) via mainband 670(2). In some examples, the semiconductor device 610(2) may transfer the data to the semiconductor device 610(1). For example, the semiconductor device 610(2) may transmit, using the routing information in the LUT 690(2), the data to semiconductor device 610(3) via mainband 670(2); the semiconductor device 610(3) may transmit, using the routing information in the LUT 690(3), the data to semiconductor device 610(4) via mainband 670(3); and the semiconductor device 610(4) may transmit, using the routing information in the LUT 690(4), the data to semiconductor device 610(1) via mainband 670(4).

In some aspects, a path containing the one or more alternative mainbands (e.g., the mainbands 670(2)-670(4) may have a lower priority than a path containing the mainband 670(1). Table 1 below is an example of routing information comprising the paths. As shown, the semiconductor devices 610(1) and 610(2) may transfer (e.g., route) data over two possible paths, path 1 or path 2. Because path 1 may have a higher priority than path 2, path 1 may be a default path and path 2 may be a backup path. For example, the semiconductor devices 610(1) and 610(2) may transfer data via the mainband 670(1), over path 1, when path 1 is functional. In the event of a failure of path 1 (e.g., a failure of the mainband 670(1)), the semiconductor devices 610(1)-610(4) may fall back to path 2 and transfer the data via the mainbands 670(2)-670(4), over path 2. A similar approach may be followed for other ports (e.g., UCIe ports) in the semiconductor devices 610(1)-610(4).

TABLE 1

| Nodes in path | Paths | Priority |
|---|---|---|
| Semiconductor device 610(1)←→ semiconductor | 1 | 0 |
| device 610(2) | | |
| Semiconductor device 610(1)←→ semiconductor | 2 | 1 |
| device 610(4) ←→ semiconductor device | | |
| 610(3) ←→ semiconductor device 610(2) | | |

In some examples, the routing information may be installed (e.g., on the LUTs 690(1)-690(4)) during design of the semiconductor package. For example, the routing information may be installed based at least in part on the topology of the semiconductor package (e.g., how the semiconductor devices 610(1)-610(4) are interconnected). Additionally, or alternatively, the routing information may be dynamically programmed or reprogrammed on the LUTs 690(1)-690(4) (e.g., responsive to a failure of the mainband 670(1)).

As indicated above, FIG. 6 is provided as an example. Other examples may differ from what is described with respect to FIG. 6.

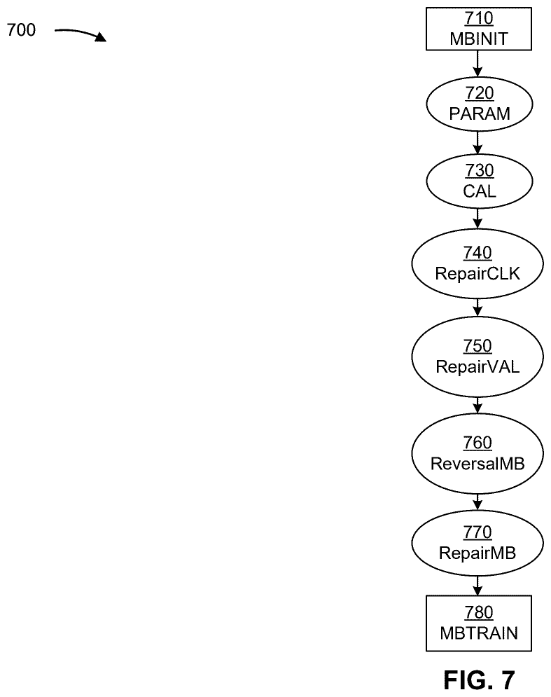

FIG. 7 is a diagram illustrating an example 700 associated with an alternative mainband mode for faulty lane identification during initialization, in accordance with the present disclosure.

Example 700 shows a plurality of substates of an MBINIT state 710, including a PARAM substate 720, a CAL substate 730, a RepairCLK substate 740, a RepairVAL substate 750, a ReversalMB substate 760, a RepairMB substate 770, and an MBTRAIN state 780. In some examples, semiconductor devices (e.g., module partners) may communicate an indication of support for an alternative mainband mode in the PARAM substate 720. For example, during initialization of a mainband between the semiconductor devices, in the PARAM substate 720, the semiconductor devices may use a sideband to check for support of the alternative mainband mode between the semiconductor devices.

In some examples, in the event of a failure of the mainband, and if mainband repair is unsuccessful, then the semiconductor devices may pause a link training state machine (e.g., a UCIe link training state machine) in the MBINIT.RepairMB substate 770 and disable a state residency timeout until the next auxiliary power domain reset. The semiconductor devices may communicate an indication to enter the alternative mainband mode in the MBINIT.RepairMB substate 770. For example, the semiconductor devices may enable the alternative mainband mode from the MBINIT.RepairMB substate 770. In the alternative mainband mode, the semiconductor devices may communicate routing information using the sideband between the semiconductor devices and transfer data over one or more alternative mainbands.

As indicated above, FIG. 7 is provided as an example. Other examples may differ from what is described with respect to FIG. 7.

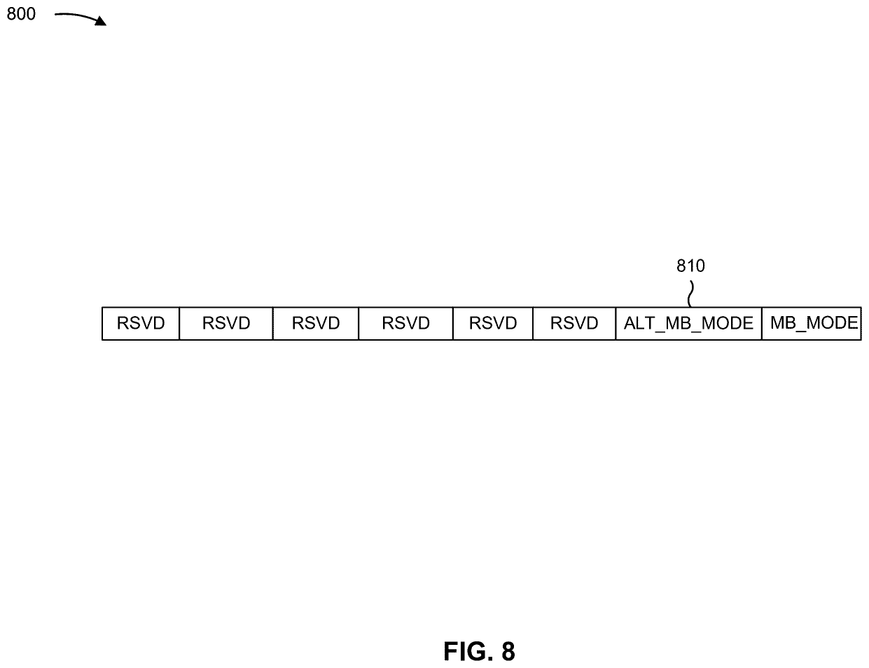

FIG. 8 is a diagram illustrating an example 800 associated with a mainband status register, in accordance with the present disclosure.

In some aspects, a semiconductor device may update a mainband status register based at least in part on the indication of support for the alternative mainband mode. For example, the semiconductor may, responsive to receiving the indication of support for the alternative mainband mode, update the mainband status register. As shown by reference number 810, the mainband status register may contain a field indicating that the alternative mainband mode (“ALT_MB_MODE”) is supported.

As indicated above, FIG. 8 is provided as an example. Other examples may differ from what is described with respect to FIG. 8.

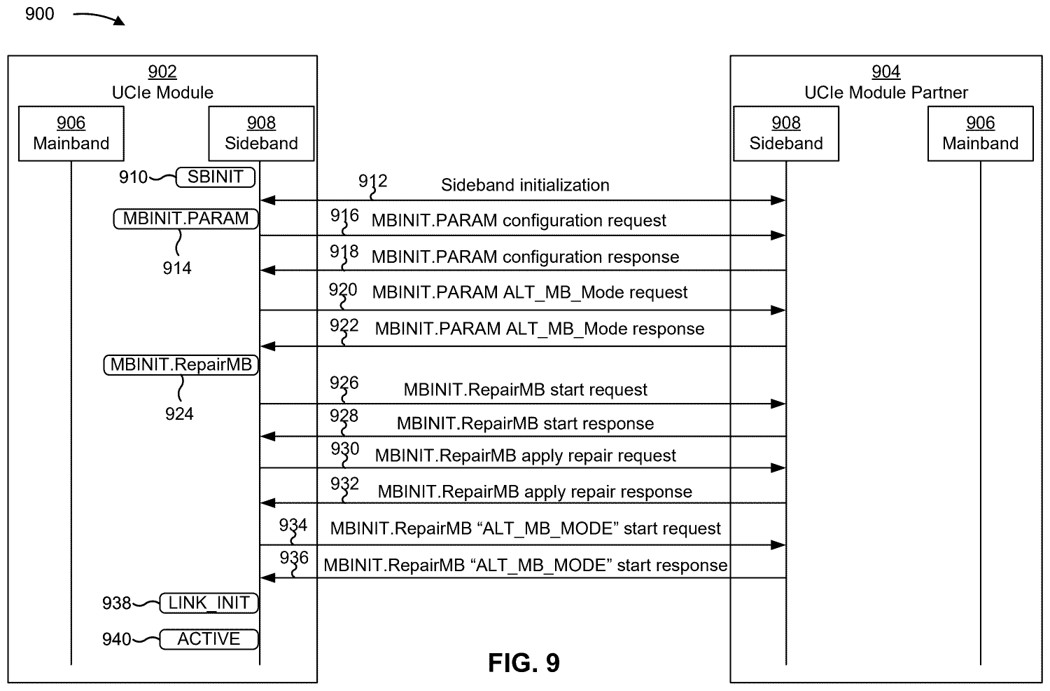

FIG. 9 is a diagram illustrating an example 900 associated with signaling for an alternative mainband mode, in accordance with the present disclosure. As shown in FIG. 9, a UCIe module 902 (e.g., a semiconductor device) and a UCIe module partner 904 (e.g., another semiconductor device) may communicate with one another via a mainband 906 and/or a sideband 908. As shown in FIG. 9, the messages between the UCIe module 902 and the UCIe module partner 904 are transmitted over the sideband 908. In some examples, the UCIe module 902 and the UCIe module partner 904 may be included in a semiconductor package (e.g., in the same semiconductor package). The UCIe module 902 and the UCIe module partner 904 may be semiconductor dies.

In an SBINIT state 910, as shown by reference number 912, the UCIe module 902 and the UCIe module partner 904 may perform sideband initialization. After the sideband initialization is complete, the UCIe module 902 and the UCIe module partner 904 may communicate via the sideband 908.

In an MBINIT.PARAM substate 914, as shown by reference number 916, the UCIe module 902 may transmit, and the UCIe module partner 904 may receive, an MBINIT.PARAM configuration request. As shown by reference number 918, the UCIe module partner 904 may transmit, and the UCIe module 902 may receive, an MBINIT.PARAM configuration response. As shown by reference number 920, the UCIe module 902 may transmit, and the UCIe module partner 904 may receive, a request for the indication of support for the alternative mainband mode. As shown by reference number 922, the UCIe module partner 904 may transmit, and the UCIe module 902 may receive, a response to the request for the indication of support for the alternative mainband mode. For example, the response may be an indication of support for the alternative mainband mode. The MBINIT.PARAM configuration request and the response to the request for the indication of support for the alternative mainband mode may be sideband messages that are used to check the feasibility of the alternative mainband mode.

In an MBINIT.RepairMB substate 924, as shown by reference number 926, the UCIe module 902 may transmit, and the UCIe module partner 904 may receive, an MBINIT.RepairMB start request. As shown by reference number 928, the UCIe module partner 904 may transmit, and the UCIe module 902 may receive, an MBINIT.RepairMB start response. As shown by reference number 930, the UCIe module 902 may transmit, and the UCIe module partner 904 may receive, an MBINIT.RepairMB apply repair request. As shown by reference number 932, the UCIe module partner 904 may transmit, and the UCIe module 902 may receive, an MBINIT.RepairMB apply repair request. As shown by reference number 934, the UCIe module 902 may transmit, and the UCIe module partner 904 may receive, a request to enter the alternative mainband mode. As shown by reference number 936, the UCIe module partner 904 may transmit, and the UCIe module 902 may receive, a response to the request to enter the alternative mainband mode (e.g., an indication to enter the alternative mainband mode). The request to enter the alternative mainband mode and the response to the request to enter the alternative mainband mode may be sideband messages that are used to move the mainband to the alternative mainband mode.

As shown by reference number 938, the UCIe module 902 and the UCIe module partner 904 may enter an LINKINIT state. As shown by reference number 940, the UCIe module 902 and the UCIe module partner 904 may enter an ACTIVE state.

Table 2 below illustrates message encodings related to a link training state machine. The message encodings may be used to read results after the training.

TABLE 2

| Message | MsgInfo[15:0] | MsgCode[7:0] | MsgSubcode[7:0] |
|---|---|---|---|
| MBINIT.PARAM | 0000h | A5h | 00h |
| configuration req | | | |
| MBINIT.PARAM | {[10:0]: Reserved | AAh | 00h |
| configuration resp | [11]: ALT_MB_Mode | | |
| | is supported | | |
| | [33]: ALT_MB_Mode | | |
| | is not supported} | | |
| {MBINIT.RepairMB | 0000h | A5h | 12h |
| Apply repair req} | | | |
| {MBINIT.RepairCLK | {[31:0]: Reserved | AAh | 12h |
| Apply repair resp} | [32]: Enabled | | |
| | ALT_MB_Mode | | |
| | [33]: Failed to | | |
| | enable ALT_MB_Mode} | | |

Table 3 below provides a description of an ALT_MB_MODE parameter.

TABLE 3

| Parameter | Description |
|---|---|
| ALT_MB_MODE | This bit may be set in each module to define |
| | whether or not data transfer through alternate |
| | mainbands is supported in that module. |

As indicated above, FIG. 9 is provided as an example. Other examples may differ from what is described with respect to FIG. 9.

Communicating an indication to enter an alternative mainband mode associated with data transfer between a first semiconductor device and a second semiconductor device via one or more alternative mainbands may help to enable data transfer (e.g., critical data transfer) between the first semiconductor device and the second semiconductor device. For example, the alternative mainband mode may provide a mechanism for handling UCIe mainband failures by enabling data transfer between the first semiconductor device and the second semiconductor device during failure of a mainband between the first semiconductor device and the second semiconductor device. The alternative mainband mode may help to keep alive a link between the first semiconductor device and the second semiconductor device during the mainband failure via a sideband between the first semiconductor device and the second semiconductor device. As a result, for example, the first semiconductor device and the second semiconductor device may access peripheral devices of the second semiconductor device and the first semiconductor device, respectively. In automotive use cases, enabling data transfer via the alternative mainband(s) may reduce risk of endangerment for passengers.

In some examples, the alternative mainband mode may enhance reliability by enabling alternate routing, which may help to ensure continuous operation without system downtime, which may be critical for high-availability systems. In some examples, the alternative mainband mode may improve fault tolerance by allowing for graceful degradation of performance rather than complete system failure, maintaining functionality even when some components fail. In some examples, the alternative mainband mode may increase system yield, including improving an overall yield of multi-die systems during manufacturing and testing, by enabling bypassing of faulty mainbands. In some examples, the alternative mainband mode may improve cost-efficiency by reducing over-provisioning or redundant systems, thereby lower costs while maintaining reliability. In some examples, the alternative mainband mode may support simplified system designs, enabling designers to create more straightforward systems without complex backup solutions. In some examples, the alternative mainband mode may increase scalability by enabling systems to be scaled using additional accessible bandwidth. In some examples, the alternative mainband mode may help to improve lifecycle management by supporting an entire silicon lifecycle, including monitoring, test, and repair of UCIe links.

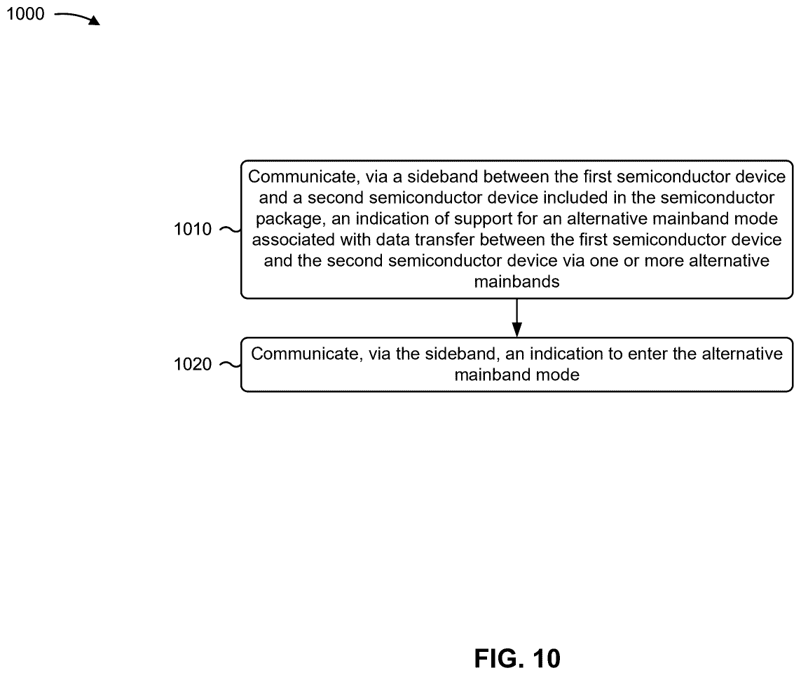

FIG. 10 is a diagram illustrating an example process 1000 performed, for example, at a first semiconductor device included in a semiconductor package or an apparatus of the first semiconductor device, in accordance with the present disclosure. Example process 1000 is an example where the first semiconductor device or the apparatus of the first semiconductor device (e.g., semiconductor device 510 or 520), performs operations associated with an alternative mainband mode.

As shown in FIG. 10, in some aspects, process 1000 may include communicating, via a sideband between the first semiconductor device and a second semiconductor device included in the semiconductor package, an indication of support for an alternative mainband mode associated with data transfer between the first semiconductor device and the second semiconductor device via one or more alternative mainbands (block 1010). For example, the first semiconductor device may communicate, via a sideband between the first semiconductor device and a second semiconductor device included in the semiconductor package, an indication of support for an alternative mainband mode associated with data transfer between the first semiconductor device and the second semiconductor device via one or more alternative mainbands, as described above.

As further shown in FIG. 10, in some aspects, process 1000 may include communicating, via the sideband, an indication to enter the alternative mainband mode (block 1020). For example, the first semiconductor device may communicate, via the sideband, an indication to enter the alternative mainband mode, as described above.

Process 1000 may include additional aspects, such as any single aspect or any combination of aspects described below and/or in connection with one or more other processes described elsewhere herein.

In a first aspect, process 1000 includes communicating a request for the indication of support for the alternative mainband mode.

In a second aspect, alone or in combination with the first aspect, process 1000 includes communicating a request to enter the alternative mainband mode.

In a third aspect, alone or in combination with one or more of the first and second aspects, communicating the indication to enter the alternative mainband mode includes communicating the indication to enter the alternative mainband mode responsive to a failure of a mainband between the first semiconductor device and the second semiconductor device.

In a fourth aspect, alone or in combination with one or more of the first through third aspects, communicating the indication of support for the alternative mainband mode includes communicating the indication of support for the alternative mainband mode in a parameter exchange substate of a mainband initialization state.

In a fifth aspect, alone or in combination with one or more of the first through fourth aspects, process 1000 includes updating a mainband status register based at least in part on the indication of support for the alternative mainband mode.

In a sixth aspect, alone or in combination with one or more of the first through fifth aspects, communicating the indication to enter the alternative mainband mode includes communicating the indication to enter the alternative mainband mode in a mainband repair substate of a mainband initialization state.

In a seventh aspect, alone or in combination with one or more of the first through sixth aspects, process 1000 includes communicating, via the sideband, in the alternative mainband mode, a reconfiguration of routing information associated with the one or more alternative mainbands.

In an eighth aspect, alone or in combination with one or more of the first through seventh aspects, the routing information is stored in a LUT.

In a ninth aspect, alone or in combination with one or more of the first through eighth aspects, process 1000 includes performing the data transfer via the one or more alternative mainbands.

In a tenth aspect, alone or in combination with one or more of the first through ninth aspects, a path containing the one or more alternative mainbands has a lower priority than a path containing a mainband between the first semiconductor device and the second semiconductor device.

Although FIG. 10 shows example blocks of process 1000, in some aspects, process 1000 may include additional blocks, fewer blocks, different blocks, or differently arranged blocks than those depicted in FIG. 10. Additionally, or alternatively, two or more of the blocks of process 1000 may be performed in parallel.

The following provides an overview of some Aspects of the present disclosure:

Aspect 1: A method performed by a first semiconductor device included in a semiconductor package, comprising: communicating, via a sideband between the first semiconductor device and a second semiconductor device included in the semiconductor package, an indication of support for an alternative mainband mode associated with data transfer between the first semiconductor device and the second semiconductor device via one or more alternative mainbands; and communicating, via the sideband, an indication to enter the alternative mainband mode.

Aspect 2: The method of Aspect 1, further comprising: communicating a request for the indication of support for the alternative mainband mode.

Aspect 3: The method of any of Aspects 1-2, further comprising: communicating a request to enter the alternative mainband mode.

Aspect 4: The method of any of Aspects 1-3, wherein communicating the indication to enter the alternative mainband mode includes communicating the indication to enter the alternative mainband mode responsive to a failure of a mainband between the first semiconductor device and the second semiconductor device.

Aspect 5: The method of any of Aspects 1-4, wherein communicating the indication of support for the alternative mainband mode includes communicating the indication of support for the alternative mainband mode in a parameter exchange substate of a mainband initialization state.

Aspect 6: The method of any of Aspects 1-5, further comprising: updating a mainband status register based at least in part on the indication of support for the alternative mainband mode.

Aspect 7: The method of any of Aspects 1-6, wherein communicating the indication to enter the alternative mainband mode includes communicating the indication to enter the alternative mainband mode in a mainband repair substate of a mainband initialization state.

Aspect 8: The method of any of Aspects 1-7, further comprising: communicating, via the sideband, in the alternative mainband mode, a reconfiguration of routing information associated with the one or more alternative mainbands.

Aspect 9: The method of Aspect 8, wherein the routing information is stored in a LUT.

Aspect 10: The method of any of Aspects 1-9, further comprising: performing the data transfer via the one or more alternative mainbands.

Aspect 11: The method of any of Aspects 1-10, wherein a path containing the one or more alternative mainbands has a lower priority than a path containing a mainband between the first semiconductor device and the second semiconductor device.

Aspect 12: An apparatus at a device, the apparatus comprising one or more processors; one or more memories coupled with the one or more processors; and instructions stored in the one or more memories and executable by the one or more processors to cause the apparatus to perform the method of one or more of Aspects 1-11.

Aspect 13: An apparatus at a device, the apparatus comprising one or more memories and one or more processors coupled to the one or more memories, the one or more processors configured to cause the device to perform the method of one or more of Aspects 1-11.

Aspect 14: An apparatus comprising at least one means for performing the method of one or more of Aspects 1-11.

Aspect 15: A non-transitory computer-readable medium storing code, the code comprising instructions executable by one or more processors to perform the method of one or more of Aspects 1-11.

Aspect 16: A non-transitory computer-readable medium storing a set of instructions, the set of instructions comprising one or more instructions that, when executed by one or more processors of a device, cause the device to perform the method of one or more of Aspects 1-11.

Aspect 17: A device comprising a processing system that includes one or more processors and one or more memories coupled with the one or more processors, the processing system configured to cause the device to perform the method of one or more of Aspects 1-11.

Aspect 18: An apparatus for wireless communication at a device, the apparatus comprising one or more memories and one or more processors coupled to the one or more memories, the one or more processors individually or collectively configured to cause the device to perform the method of one or more of Aspects 1-11.

The foregoing disclosure provides illustration and description but is not intended to be exhaustive or to limit the aspects to the precise forms disclosed. Modifications and variations may be made in light of the above disclosure or may be acquired from practice of the aspects.

As used herein, the term “component” is intended to be broadly construed as hardware or a combination of hardware and at least one of software or firmware. “Software” shall be construed broadly to mean instructions, instruction sets, code, code segments, program code, programs, subprograms, software modules, applications, software applications, software packages, routines, subroutines, objects, executables, threads of execution, procedures, or functions, among other examples, whether referred to as software, firmware, middleware, microcode, hardware description language, or otherwise. As used herein, a “processor” is implemented in hardware or a combination of hardware and software. It will be apparent that systems or methods described herein may be implemented in different forms of hardware or a combination of hardware and software. The actual specialized control hardware or software code used to implement these systems or methods is not limiting of the aspects. Thus, the operation and behavior of the systems or methods are described herein without reference to specific software code, because those skilled in the art will understand that software and hardware can be designed to implement the systems or methods based, at least in part, on the description herein. A component being configured to perform a function means that the component has a capability to perform the function, and does not require the function to be actually performed by the component, unless noted otherwise.

As used herein, “satisfying a threshold” may, depending on the context, refer to a value being greater than the threshold, greater than or equal to the threshold, less than the threshold, less than or equal to the threshold, equal to the threshold, or not equal to the threshold, among other examples.

As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (for example, a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” and similar terms are intended to be open-ended terms that do not limit an element that they modify (for example, an element “having” A may also have B). Further, the phrase “based on” is intended to mean “based on or otherwise in association with” unless explicitly stated otherwise. Also, as used herein, the term “or” is intended to be inclusive when used in a series and may be used interchangeably with “and/or,” unless explicitly stated otherwise (for example, if used in combination with “either” or “only one of”). It should be understood that “one or more” is equivalent to “at least one.”

Even though particular combinations of features are recited in the claims or disclosed in the specification, these combinations are not intended to limit the disclosure of various aspects. Many of these features may be combined in ways not specifically recited in the claims or disclosed in the specification. The disclosure of various aspects includes each dependent claim in combination with every other claim in the claim set.

What is claimed is:

1. An apparatus, comprising:
a first semiconductor device, included in a semiconductor package, configured to:
communicate, via a sideband between the first semiconductor device and a second semiconductor device included in the semiconductor package, an indication of support for an alternative mainband mode associated with data transfer between the first semiconductor device and the second semiconductor device via one or more alternative mainbands; and
communicate, via the sideband, an indication to enter the alternative mainband mode.

2. The apparatus of claim 1, wherein the first semiconductor device is further configured to:
communicate a request for the indication of support for the alternative mainband mode.

3. The apparatus of claim 1, wherein the first semiconductor device is further configured to:
communicate a request to enter the alternative mainband mode.

4. The apparatus of claim 1, wherein the first semiconductor device, to communicate the indication to enter the alternative mainband mode, is configured to communicate the indication to enter the alternative mainband mode responsive to a failure of a mainband between the first semiconductor device and the second semiconductor device.

5. The apparatus of claim 1, wherein the first semiconductor device, to communicate the indication of support for the alternative mainband mode, is configured to communicate the indication of support for the alternative mainband mode in a parameter exchange substate of a mainband initialization state.

6. The apparatus of claim 1, wherein the first semiconductor device is further configured to:
update a mainband status register based at least in part on the indication of support for the alternative mainband mode.

7. The apparatus of claim 1, wherein the first semiconductor device, to communicate the indication to enter the alternative mainband mode, is configured to communicate the indication to enter the alternative mainband mode in a mainband repair substate of a mainband initialization state.

8. The apparatus of claim 1, wherein the first semiconductor device is further configured to:
communicate, via the sideband, in the alternative mainband mode, a reconfiguration of routing information associated with the one or more alternative mainbands.

9. The apparatus of claim 8, wherein the routing information is stored in a lookup table (LUT).

10. The apparatus of claim 1, wherein the first semiconductor device is further configured to:
perform the data transfer via the one or more alternative mainbands.

11. The apparatus of claim 1, wherein a path containing the one or more alternative mainbands has a lower priority than a path containing a mainband between the first semiconductor device and the second semiconductor device.

12. A method performed by a first semiconductor device included in a semiconductor package, comprising:
communicating, via a sideband between the first semiconductor device and a second semiconductor device included in the semiconductor package, an indication of support for an alternative mainband mode associated with data transfer between the first semiconductor device and the second semiconductor device via one or more alternative mainbands; and
communicating, via the sideband, an indication to enter the alternative mainband mode.

13. The method of claim 12, further comprising:
communicating a request for the indication of support for the alternative mainband mode.

14. The method of claim 12, further comprising:
communicating a request to enter the alternative mainband mode.

15. The method of claim 12, wherein communicating the indication to enter the alternative mainband mode includes communicating the indication to enter the alternative mainband mode responsive to a failure of a mainband between the first semiconductor device and the second semiconductor device.

16. The method of claim 12, wherein communicating the indication of support for the alternative mainband mode includes communicating the indication of support for the alternative mainband mode in a parameter exchange substate of a mainband initialization state.

17. The method of claim 12, further comprising:
updating a mainband status register based at least in part on the indication of support for the alternative mainband mode.

18. The method of claim 12, wherein communicating the indication to enter the alternative mainband mode includes communicating the indication to enter the alternative mainband mode in a mainband repair substate of a mainband initialization state.

19. An apparatus included in a semiconductor package, comprising:
means for communicating, via a sideband between the apparatus and another apparatus included in the semiconductor package, an indication of support for an alternative mainband mode associated with data transfer between the apparatus and the other apparatus via one or more alternative mainbands; and
means for communicating, via the sideband, an indication to enter the alternative mainband mode.

20. The apparatus of claim 19, wherein the apparatus further comprises:
means for communicating a request for the indication of support for the alternative mainband mode.
